(19) United States
(12) Patent Application Publication
(10) Pub. No.: US 2018/0172600 A1
(43) Pub. Date: Jun. 21, 2018

(54) CHARACTERIZING THE EMISSION PROPERTIES OF SAMPLES

(71) Applicant: Roche Diagnostics Operations, Inc., Indianapolis, IN (US)

(72) Inventor: Joachim Wietzorrek, Zug (CH)

(73) Assignee: Roche Diagnostics Operations, Inc., Indianapolis, IN (US)

(21) Appl. No.: 15/838,880

(22) Filed: Dec. 12, 2017

(30) Foreign Application Priority Data
Dec. 16, 2016 (EP) 16204804.5

(51) Int. Cl. G01N 21/88; G02B 17/08; G03F 7/20

(52) U.S. Cl. CPC G01N 21/8806; G02B 17/0808; G02B 27/0025; G03F 7/70225; G03F 7/70341; G02B 17/0856

(57) ABSTRACT

The present disclosure relates to a method for characterizing a light source. The method includes providing a light source to be characterized, collecting light emitted from the light source by using imaging optics, the imaging optics generating a pupil of the collected light emitted from the light source, generating an image of a pupil of light emitted only from a first surface area of the light source at a detector using the imaging optics, laterally shifting the light source and the imaging optics relative to each other and after the lateral shift, generating an image of a pupil of light emitted only from a second surface area of the light source at the detector using the imaging optics. The imaging optics includes a field stop between the light source and the detector to select a portion of the light source's surface from which light is imaged at a time.

### CROSS-REFERENCE TO RELATED APPLICATIONS

This application is based on and claims priority to EP 16204804.5, filed Dec. 16, 2016, which is hereby incorporated by reference.

### BACKGROUND

The present disclosure relates to methods for characterizing light sources and samples and to devices and analyzers for characterizing light sources and samples.

The task of characterizing the emission characteristics of a light emitting sample plays an important role in many fields. For example, it might be desirable to characterize a light source to be deployed in an automated analyzer for samples (e.g., an in-vitro analyzer). This characterization can include detecting the angular emission pattern of the light source, as well as the spatial distribution of the light emission over the light source's surface. One known technique to characterize a light source in this manner is the goniometric approach. In a goniometer, a detector is moved about the light source to be characterized and captures light emitted from the light source in different directions. In some examples, spatially resolved images are taken at each angular position by a matrix detector. This technique is called near-field goniometry (the light source to be characterized is not considered as a point source). Goniometers can require fairly bulky and complex mechanical arrangements. Therefore, some of these devices can be comparatively large and expensive.

### SUMMARY

According to the present disclosure, a method for characterizing a light source is presented. The method can comprise providing a light source to be characterized, collecting light emitted from the light source by using imaging optics. The imaging optics can generate a pupil of the collected light emitted from the light source. The method can further comprise generating an image of a pupil of light emitted only from a first surface area of the light source at a detector using the imaging optics, laterally shifting the light source and the imaging optics relative to each other, and, after the lateral shift, generating an image of a pupil of light emitted only from a second surface area of the light source at the detector using the imaging optics. The imaging optics can include a field stop between the light source and the detector to select a portion of the light source's surface from which light is imaged at a time.

In accordance with one embodiment of the present disclosure, an analyzer for analyzing a sample is presented. The analyzer can comprise a sample support for receiving a sample to be analyzed, a matrix detector, and imaging optics configured to collect light emitted from the sample, generate a pupil of the collected light emitted from the sample, generate an image of the pupil of the sample at a matrix detector so that rays having different angular directions when emanating from the sample are imaged onto different locations at the matrix detector.

Other features of the embodiments of the present disclosure will be apparent in light of the description of the disclosure embodied herein.

### BRIEF DESCRIPTION OF THE SEVERAL VIEWS OF THE DRAWINGS

The following detailed description of specific embodiments of the present disclosure can be best understood when read in conjunction with the following drawings, where like structure is indicated with like reference numerals and in which:

FIG. 1 illustrates an example characterization system for characterizing a light source according to an embodiment of the present disclosure.

FIG. 2 illustrates a portion of a characterization system for characterizing a light source including a second arm for adjustment purposes according to an embodiment of the present disclosure.

FIG. 3 illustrates an example characterization system for characterizing light sources including a first measurement arm and a second adjustment arm according to an embodiment of the present disclosure.

FIG. 4 illustrates an example pupil image generated by the techniques of the present disclosure and an image of a surface of a light-emitting device reconstructed based on the pupil image according to an embodiment of the present disclosure.

FIG. 5 illustrates an example characterization system for a sample according to an embodiment of the present disclosure.

FIG. 6a illustrates example rays emanating from the surface of the sample according to an embodiment of the present disclosure.

FIG. 6b illustrates example rays focused by a field lens array according to an embodiment of the present disclosure.

### DETAILED DESCRIPTION

In the following detailed description of the embodiments, reference is made to the accompanying drawings that form a part hereof, and in which are shown by way of illustration, and not by way of limitation, specific embodiments in which the disclosure may be practiced. It is to be understood that other embodiments may be utilized and that logical, mechanical and electrical changes may be made without departing from the spirit and scope of the present disclosure.

A method for characterizing a light source is disclosed. The method can include providing a light source to be characterized and collecting light emitted from the light source by using imaging optics. The imaging optics can generate a pupil of the collected light emitted from the light source. The method can also include generating an image of a pupil of light emitted only from a first surface area of the light source at a detector using the imaging optics, laterally shifting the light source and the imaging optics relative to each other and after the lateral shift, and generating an image of a pupil of light emitted only from a second surface area of the light source at the detector using the imaging optics. The imaging optics can include a field stop between the light source and the detector to select a portion of the light source's surface from which light is imaged at a time. A device for characterizing a light source can be configured to perform the operations of the above method.

A method of analyzing a sample in an analyzer for samples is presented. The method can include collecting light emitted from the sample by using imaging optics. The imaging optics can be further configured to generate a pupil of the collected light emitted from the sample. The method can also include generating an image of the pupil of the sample at a matrix detector using the imaging optics so that rays having different angular directions when emanating from the sample are imaged onto different locations at the matrix detector. An analyzer for analyzing sample can be configured to carry out the operations according to the above method.

The above methods and devices can have one of more of the following advantages in some embodiments.

Firstly, by employing pupil imaging techniques to characterize light sources or samples (e.g., samples in an in-vitro analyzer), the techniques of the present disclosure can provide a relatively cost efficient way to characterize the spatial and angular emission properties of light sources or samples.

Some prior art characterization techniques to characterize the spatial and angular emission properties of light sources or samples use goniometric techniques. These techniques can require relatively large and expensive devices for moving a matrix detector about a light source or sample to be characterized.

For carrying out the techniques of the present disclosure, on the other hand, only relatively simple mechanical components may be required in some examples. For instance, a translational actuator to move a light source, or a sample, in two translational dimensions may be sufficient. In other examples, the techniques of the present invention can characterize an extended light emitting sample spatially and angularly without moving parts. In this manner, the setups required to carry out the techniques of the present disclosure may be more compact and cost-efficient than some prior art solutions in some situations.

Secondly, the pupil imaging techniques of the present disclosure can be employed in analyzers, e.g., in vitro analyzers for analyzing samples. Here, the techniques of the present disclosure can be used to characterize the angular emission properties of samples (e.g., of a liquid analyte). This can provide additional information regarding the sample to be analyzed compared to some known solutions.

For example, in an in vitro analyzer operating in transmission employing the techniques of the present disclosure, the angular emission characteristics of a sample can be measured. In contrast to that, some known analyzers only obtain a single transmission value/absorption value for a sample at a given wavelength. The additional information obtained when using the techniques of the present disclosure can be useful to deduce different properties of the sample.

Thirdly, the pupil imaging systems of the present disclosure can be integrated relatively easily in common analyzer setups in some situations. For example, some analyzers use a microscope-type setup to characterize the optical properties of a sample (e.g., the absorption of a sample). It may be difficult to integrate a goniometric set-up in these systems without considerable design changes.

The systems of the present disclosure, on the other hand, can be realized in a microscope set-up (or other known analyzer setups) without a significant number of changes to the arrangement of the components in some examples. As a consequence, the systems of the present disclosure can be integrated in existing analyzers without requiring a substantial re-design of the analyzer. In this manner, the systems of the present disclosure may be employed in existing analyzer setups without adding excessively to the complexity and thus the cost of the system.

The term ‘light’ can be used in the present disclosure as not limited to radiation in the visible wavelength range (e.g., between 400 nm and 780 nm). Rather, light can also include radiation in the IR- or UV-range. For example, light can include radiation in a wavelength range between 150 nm and 2000 nm (e.g., between 250 nm and 1600 nm).

In the present disclosure, the expressions ‘light emitted from a surface/surface area’ may not mean that the light generation process actually takes place at the respective surface or surface area. Rather, the expression ‘emitted from’ can indicate that the light can exit the surface at the respective position. The term ‘emanating from’ can be used in the same sense.

The term ‘optics’ can be used in the present disclosure to refer to any assembly of one or more optical elements arranged to perform a particular task. For example, optics can include a plurality of lens elements arranged to steer light from an input plane to an output plane. In addition, optics can include further elements to filter or shape the light traversing the optics. For example, optics can include field stops or aperture stops, or wavelength selective filters. The elements of the optics can also be (at least partially) integrated in some examples.

The term ‘imaging optics’ can be used to refer to any optics which can substantially preserve the order of a set of rays propagating through the optics. For example, imaging optics can be configured to create an image of a field, or a pupil, of an object. Thus, imaging optics may not be limited to assemblies configured to generate an image of an object. Rather, and imaging optics can also be configured to generate an image of a pupil of an object (i.e. a defocused image of the field of the object), or a partially defocused image.

The term ‘pupil’ can be used in the present disclosure as referring to an image of an aperture of a system. In other words, in the pupil rays propagating at a predetermined angle to a central axis of the optical system can meet at the same point. For example, in the pupil of light emanating from a light-emitting surface, all rays exiting the light-emitting surface under a certain angle can meet at the same point. Thus, each position in the pupil can represent all the rays exiting the surface under the particular angle. Sharp points of the light-emitting surface can be defocused in the pupil (and vice-versa). The pupil and images of the light-emitting surface can be optically conjugated.

Depending on the layout of the optical system, there can be multiple replicas of the pupil along the optical path. In other words, a pupil formed by the optics can be imaged to a plane further downs the optical path (and this can happen multiple times in some systems).

The pupil does not have to coincide with an element of the imaging optics.

The terms ‘analyzer’/‘analytical work cell’/‘analytical unit’ as used herein can encompass any apparatus, or apparatus component, that can measure analytical properties of a sample, e.g., following a reaction of a sample with a reagent for obtaining a measurement value.

An analyzer can be operable to determine one or more parameters of a sample or a component thereof. For example, a parameter can be an absorption, transmittance or reflectance of the sample contained in a cuvette or other sample vessel. In other examples, a parameter can be a fluorescence of a sample after having been illuminated with excitation light. Apart from the optical measurement devices of an analyzer discussed below (e.g., to determine an absorption, transmittance or reflectance), an analyzer can include measurement devices to determine a parameter of the sample via one or more chemical, biological, physical, or other technical procedures.

An analyzer may be operable to determine the parameter of the sample or of at least one analyte, process the determined parameter and return an obtained measurement value. The list of possible analysis results returned by the analyzer comprises, without limitation, concentrations of the analyte in the sample, a qualitative (yes or no) result indicating the existence of the analyte in the sample (corresponding to a concentration above the detection level), optical parameters, DNA or RNA sequences, data obtained from mass spectroscopy of proteins or metabolites and physical or chemical parameters of various types.

An analytical work cell may comprise units for pipetting, dosing, and mixing of samples and/or reagents. The analyzer may comprise a reagent holding unit for holding reagents to perform the assays. Reagents may be arranged for example in the form of containers, or cassettes, containing individual reagents or group of reagents, placed in appropriate receptacles or positions within a storage compartment or conveyor. It may comprise a consumable feeding unit.

The analyzer may comprise a process and detection system whose workflow can be optimized for certain types of analysis. Examples of such analyzers can be clinical chemistry analyzers, coagulation chemistry analyzers, immunochemistry analyzers, urine analyzers, hematology analyzers, nucleic acid analyzers, used to detect the result of chemical or biological reactions or to monitor the progress of chemical or biological reactions.

The term ‘sample’ can refer to material(s) that may potentially contain an analyte of interest. In some examples, the sample can be a liquid sample. The sample can be derived from a biological source, such as a physiological fluid, including blood, saliva, ocular lens fluid, cerebrospinal fluid, sweat, urine, stool, semen, milk, ascites fluid, mucous, synovial fluid, peritoneal fluid, amniotic fluid, tissue, cultured cells, or the like. The biological sample can be pretreated prior to use, such as preparing plasma from blood. Methods of treatment can involve centrifugation, filtration, distillation, dilution, concentration and/or separation of sample components including analytes of interest, inactivation of interfering components, and the addition of reagents. A sample may be used directly as obtained from the source or used following a pretreatment to modify the character of the sample. In some embodiments, an initially solid or semi-solid biological material can be rendered liquid by dissolving or suspending it with a suitable liquid medium. In some examples, the sample can be suspected to contain a certain antigen or nucleic acid.

Unless specified otherwise, the term ‘substantially’ in the present disclosure can refer to a deviation of +/−10% from a predetermined value. For example, if the length of two elements is substantially equal, their actual length can differ by up to 10%. In the same manner, if an intensity distribution is substantially homogeneous, deviations from up to 10% from an average value might occur.

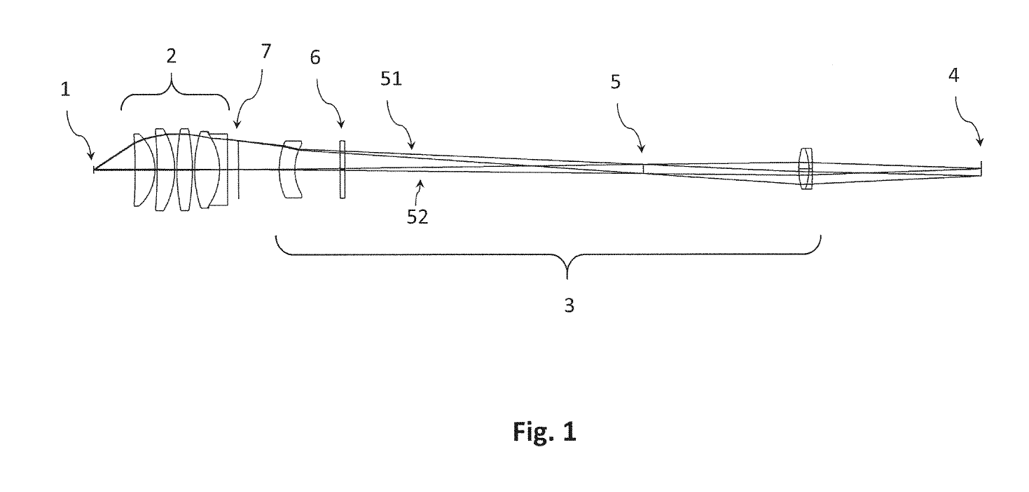

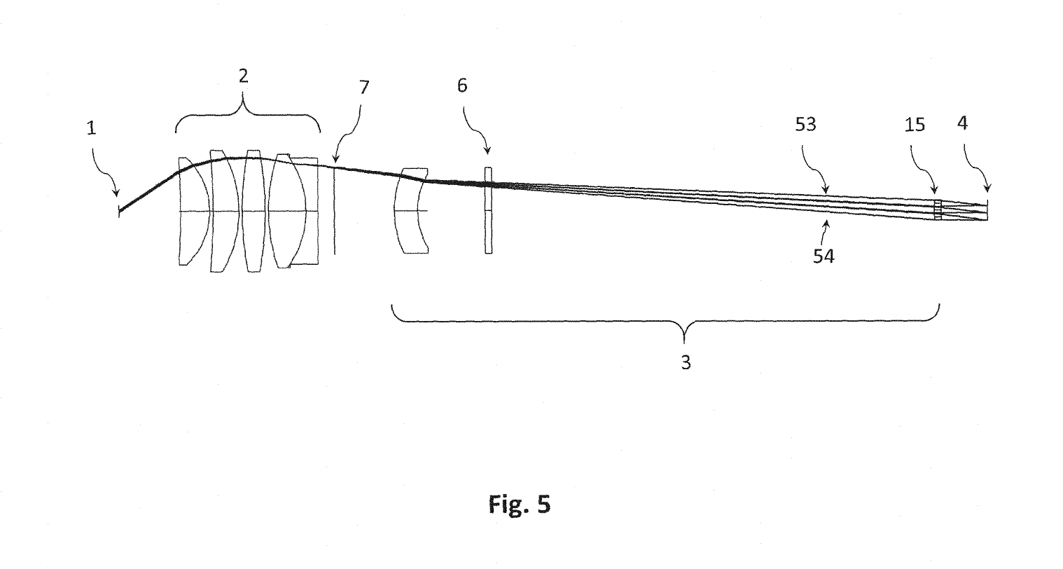

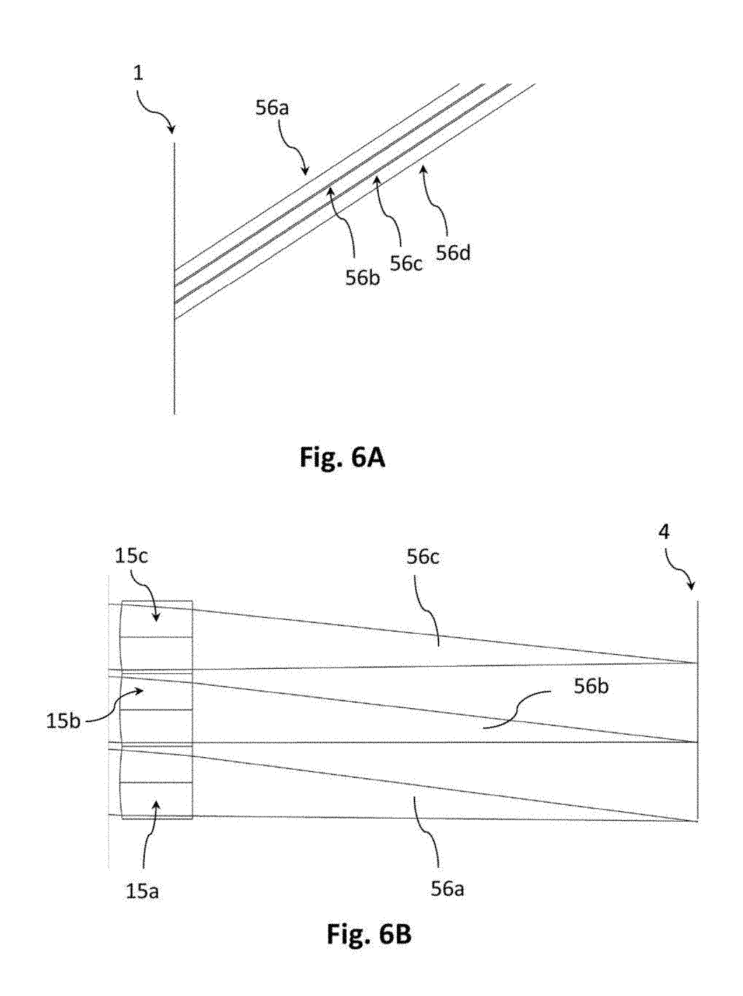

The detailed description is split into two main parts. First, in connection with FIGS. 1 to 3, aspects of characterization devices and methods to characterize the emission properties of a light source will be explained. Subsequently, in connection with FIG. 5 and FIGS. 6a-b, the analyzers and methods for characterizing a sample according to the present disclosure will be discussed. It can be pointed out that the techniques for characterizing a light source and the techniques for characterizing a sample discussed herein deploy the same underlying principle of pupil imaging. Therefore, aspects discussed herein in connection with the devices and methods for characterizing a light source can also be deployed in the devices and methods for characterizing a sample discussed herein, and vice versa (unless the particular aspect is incompatible with the peculiarities of the respective device or method).

Having said that, FIG. 1 shows an example device for characterizing a light source. The device can include a support 1 for receiving a light source to be characterized, a detector 4, imaging optics 2, 3 and a translation actuator (not shown in FIG. 1).

The imaging optics 2, 3 can be configured to collect light emitted from the light source, to generate a pupil 7 of the collected light emitted from the light source and to generate an image of a pupil of light emitted only from a particular surface area of the light source at the detector 4. The translation actuator can be configured to laterally shift the support 1 and the imaging optics 2, 3 relative to each other.

The system can further include a controller (not shown in FIG. 1) configured to laterally shift the support 1 and the imaging optics 2, 3 relative to each other and to control the detector 4 to generate an image of a pupil of light emanating only from a particular surface area of the light source at the detector 4.

The imaging optics 2, 3 can include a field stop 5 between the support for receiving a light source 1 and the detector 4 to select a portion of the light source's surface from which light is imaged at a time.

In the following sections, the operation of the system of FIG. 1 will be explained. Subsequently, the different element of the device for characterizing a light source and their possible configuration will be discussed in more detail.

As can be seen in FIG. 1, light can emanate from a light source arranged in the support 1 in different angular directions. FIG. 1 shows example groups of rays emanating from the light source's surface. A first group of rays 52 can travel substantially along a main axis of the imaging optics 2, 3 (in an orthogonal direction relative to the surface of the light source). A second group of rays 51 can exit the surface of the light source under an angle.

In the example of FIG. 1, the angle of the second group of rays 51 can be a maximum angle that can still be captured by the imaging optics 2, 3. In other words, the angle of the second group of rays 51 can correspond to the input numerical aperture of the imaging optics 2, 3.

Even though it cannot be clearly seen on the left hand side in FIG. 1, each of the first and second group of rays 51, 52 can include a plurality of rays emanating from the surface of the light source (e.g., being slightly displaced in a transversal direction). The reason for that is that the light source can be spatially extended so that light can exit the light source's surface at different positions. This situation is illustrated in FIG. 6a which shows an enlarged view of a group of rays exiting the surface of a light emitting sample. This can also be seen when following the path of the rays further down the imaging optics 2, 3 to the region between the pupil 7 and the field stop 5. Each of the first and second group of rays 51, 52 can include rays emanating from different spatial positions on the light source's surface which therefore propagate under different angles between the pupil 7 and the field stop 5.

Now, the imaging optics can generate a pupil 7 of the collected light emanating from the light source. As can be seen, the first group of rays 52 can traverse the pupil 7 in a central position. All the rays of their first group of rays can meet at the same position in the pupil 7. Likewise, the rays of the second group of rays 51 can meet in the pupil 7 at a different spatial position. As the second group of rays 51 corresponds to rays propagating under the maximum angle that can be collected by the imaging optics 2, 3, the position can be a most outward position in the pupil 7. Even though only two group of rays 51, 52 are shown in FIG. 1 for the sake of illustration, it can easily be seen that groups of rays exiting the surface of the light source under different angles than the first and second groups of rays 51, 52 (i.e., under intermediate angles) are likewise being imaged onto the pupil 7 at different spatial positions. All the rays collected from the light source light source can traverse the pupil 7, wherein a spatial position in the pupil 7 can correspondence to a particular angular direction of the respective rate when exiting the surface of the light source.

This pupil 7 can subsequently be imaged onto the detector 4 by the imaging optics 2, 3 of the system of FIG. 1. Therefore, the spatial position of a ray on the detector 4 can also correspond to a particular angle under which the rays can exit the surface of the light emitting device. In other words, the rays can be ‘sorted’ according to their emission angle at the detector 4.

However, the pupil 7 in FIG. 1 constitutes an average pupil averaged over the complete surface of the light emitting device from which light can be collected by the imaging optics 2, 3. Thus, the imaging optics 2, 3 can additionally include the field stop 5 configured to restrict the area of the light-emitting devices surface which can be imaged at a time. This will be explained more detail next.

As can be seen in FIG. 1, the field stop 5 can be located in an intermediate field plane of the imaging optics 2, 3. Thus, at the position of the field stop 5, an image of the surface of the light emitting device located in the support 1 can be formed. By selecting a portion of this image, only rays emanating from this particular portion of the surface of the light-emitting device can be imaged onto the detector 4. The rays emanating from other surface areas can be blocked by the field stop 5.

The size of the area of the surface imaged at the time can be selected by selecting the size of the field stop 5. In this manner, the device of FIG. 1 can generate a local or spatially resolved pupil image of the particular surface area of the light emitting device (instead of an average pupil image over the complete surface area from which light can be collected which would be generated if the field stop 5 was not present).

In order to generate a spatially resolved image of the light emitting devices surface, the imaging optics 2, 3 and the support 1 for the light-emitting device can be translated relative to each other. For example, after generating a pupil image of a first surface area of the light-emitting device, the translation actuator can change the relative position of the support 1 and the imaging optics 2, 3. In this manner, the field stop 5 can select a second, different portion of the surface area of the light-emitting device. Then, an image of this second surface area of the light emitting device can be generated on the detector 4.

This procedure can be repeated multiple times. In this fashion, the complete surface of the light-emitting device, or a particular fraction of the surface of the light-emitting device can be imaged in a step like manner.

In some examples, a surface area scanned in the above described manner can be (much) larger than a field of view of the imaging optics 2, 3. In this manner, extended light sources (e.g., arrays of multiple LEDs) can be analyzed. However, in other examples, the surface area scanned can be smaller than a field of view of the imaging optics 2, 3.

The resulting data can constitute a complete characterization of the spatial and angular emission characteristics of the light source (at least of the portion of the emission characteristics which can be collected by the imaging optics 2, 3 due to the limited numerical aperture of the imaging optics 2, 3). As a consequence, the spatial and angular emission characteristics of the light source can be reconstructed from the serious of images taken by the system of FIG. 1.

It has been explained above that the dimension of the field stop 5 can determine the size of the surface area whose light reaches the detector 4 at a time. Accordingly, the translation of the imaging optics 2, 3 relative to the support can be selected to cover the complete surface area. In some examples, the field stop 5 can be larger so that light from a larger surface of the light source can reach the detector 4. In other cases, the field stop 5 can be smaller so that light from a smaller surface of the light source can reach the detector 4. Accordingly, a length of a step of the translation can be larger or smaller, respectively. In other words, the size of the field stop can determine a resolution of the characterization process of the light source and the stepping motion.

In some examples, the detector 4 can register intensity data of the rays of light in the pupil images (e.g., a photon count at each position of the detector). This intensity data can be an indicative of an intensity of the light exiting the light sources surface under the respective angle at the particular portion of the light source's surface. The intensity data can be added to the data set characterizing the light source's emission pattern.

Thus, the resulting dataset can be resolved in two spatial dimensions over the surface of the light source, two angular dimensions and can additionally include intensity data. In other words, the system of FIG. 1 can generate a five dimensional dataset characterizing the emission properties of the light source. As explained above, this can be possible by only effecting a relative translation of the support 1 and the imaging optics 2, 3 in two linear directions. In particular, no rotating movement of the detector about the light source to be analyzed may be necessary (such as in goniometric setups). However, in some examples, the light source to be characterized can be moved in additional directions. For example, the light source can be turned (e.g., in a step-wise manner) in some examples.

In addition, depending on an extension of the light source, the traveling path of the translation movements can be relatively low. Therefore, characterizing the emission properties of a light source by using the system of FIG. 1 can be relatively cost and space efficient in some examples.

After the general operation principle of the system of FIG. 1 has been explained in the preceding sections, the different components of the system of FIG. 1 will be discussed in more detail subsequently.

As can be seen, the imaging optics 2, 3 of FIG. 1 can include a first optics assembly 2 and a second optics assembly 3. The first optics assembly 2 can be configured to collect light emanating from the light source arranged in the support 1. Moreover, the first optics assembly 2 can be configured to generate the pupil 7 of the collected light in its back focal plane. In one example, the first optics assembly can be a collector (e.g. a collector of a microscope set up).

An input numerical aperture of the first optics assembly 2 (e.g., the collector) can limit the range of angles of rays the characterization device of FIG. 1 can detect (at least without rotating the sample).

As can be seen, the first optics assembly 2 can include a plurality of optical components (e.g., five lens elements in the example of FIG. 1). However, any optics assembly suitable to collect light from the light source and to generate a pupil of the light collected from the light emitting device can be used. For example, the first optics assembly 2 may only include a smaller number of lens elements (e.g. one or two lens elements) in some examples, or different lens elements than the lens elements shown in FIG. 1. It may be necessary to include a plurality of optical components to meet particular design criteria depending on the circumstances (e.g., to provide a predetermined level of correction of imaging errors and/or to provide predetermined numerical aperture or field of view of the imaging system or to meet a price criterion). Therefore, the setup of the first optical assembly 2 can be fairly different in other examples using the techniques of the present disclosure.

In general, the first optics assembly 2 can be sine corrected. In this manner, a distance of a particular ray of the center of the pupil 7 can be directly associated with the angle under which the respective ray exits the surface of the light source (e.g., the distance can be proportional to the cosine of the angle). Without the sine correction, there may be deviations from this direct correspondence which can make the pupil images more difficult to interpret.

In addition to the first optics assembly 2, the imaging optics 2, 3 can include a second optical assembly 3 which can be arranged to relay the pupil 7 onto the detector plane of the detector 4. In other words, the pupil 7 can be replicated on the detector 4 by the second optical assembly 3. In one example, the second optical assembly 3 can be a tube lens.

It can be seen in FIG. 1 that the second optical assembly 3 can include three lens elements (i.e., a meniscus lens and a doublet). Again, the concrete implementation of the second optical assembly 3 might be different and other examples of the present disclosure.

In other examples, the imaging optics can include further optical assemblies which can generate further replicas of the pupil. For example, in a different example of imaging optics according to the present disclosure, there can be an intermediate replica of the pupil between the pupil and the image of the pupil captured by the detector.

In still other examples, the detector may be arranged at the first pupil generated by the imaging optics (e.g., at the position of pupil 7 in FIG. 1). In this example, the field stop 5 can be arranged between the pupil 7 and the surface of the light source (e.g., adjacent to the light source).

The detector 4 can be a matrix detector configured to capture a spatially resolved image. For example, the detector 4 can be a CMOS or CCD detector. However, all other matrix detectors can also be used. In some examples, the detector 4 can also be a single pixel detector which can be scanned to collect rays at different spatial positions in the detector plane.

As explained above, the device of FIG. 1 can also include a wavelength selective filter 6 arranged in the second optics assembly 3. This wavelength selective filter 6 can be selected to only let pass a particular portion of the spectral band of the light exiting the light source. This can reduce chromatic effects due to rays at different wavelength being imaged to different spatial positions at the detector, even though these rays emanate from the surface of the light-emitting device under identical angles (and vice versa). This may happen due to chromatic aberrations of the imaging system and may impair the characterization capabilities of the system.

In other examples, the wavelength selective filter can be located at different positions of the device (e.g., at a different position in the imaging optics 2, 3). For examples, a wavelength selective filter can be arranged at or near the detector 4. In still other examples, there may not be a wavelength selective filter in device.

In some examples, the system can be configured to include filters with different pass bands to sequentially capture images in different wavelength bands. In this manner, the characterization of the light source can also be resolved wavelength-wise. For example, the filter 6 might be a tunable filter or can include a set of different filters that can be selectively moved into the optical path (e.g., a set of different filters in a filter wheel). In some examples, the controller of the imaging system might be configured to automatically tune the wavelength characteristics of the tunable filter 6.

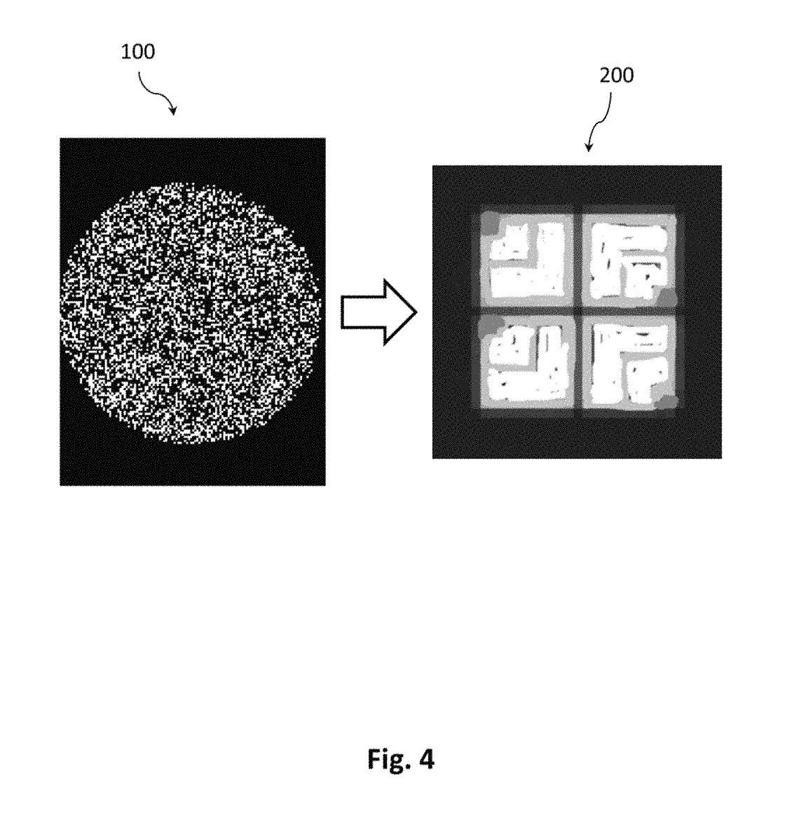

It has been explained above how a pupil of the light source's light collected by the imaging optics can be generated. An example pupil image which can be generated by using the techniques of the present disclosure is shown in FIG. 4. The pupil image 100 is depicted on the left-hand side of FIG. 4. As can be seen, the pupil image 100 shows that a different number of rays can exit the surface of the light-emitting device under different angles. For instance, a region in a central position of the pupil image 100 can represent light exiting the light source's surface in a substantially perpendicular direction. In the same manner, a region in a fringe position of the pupil image 100 can represent light exiting the light source's surface under an angle corresponding to the input numerical aperture of the imaging optics.

As FIG. 4 comprises only a black and white drawing, the intensity information which may be present in the pupil image 100 is not visible in FIG. 4. However, it can be seen that each pixel of the pupil image 100 can carry intensity information.

As explained above, the characterization device of the present disclosure can capture a series of pupil images similar to pupil image 100 associated with different surface areas of the light emitting device. This set of pupil images can then be used to characterize the emission characteristics of the light source. For example, it can be possible to generate a map of the emission intensity of the light source over the surface of the light source. Such map 200 is shown on the right-hand side of FIG. 4. As can be seen, the example light source can include four LEDs arranged in a square array.

However, the dataset obtained by the system of the present disclosure can also include the angular characteristics of the emission of the light source. Therefore, spatially resolved images such as image 200 can also be generated for any other direction under which the characterized light source can be observed.

In addition or alternatively, the data generated by the system of the present disclosure can also be processed into many different other representations. For example, an emission pattern at an arbitrary spaced-apart position from the light-source can be determined. As already explained, the emission data can be limited to a particular cone corresponding to the input numerical aperture of the imaging optics.

In still other examples, a different representation of the light source's emission characteristics based on the multiple images of pupils of light emitted from multiple surface areas specifying spatial and angular emission characteristics of the light source can be generated. For example, the representation may not have to be a graphical representation in some examples. For instance, a representation can include a textual or numeric presentation of ray data or other data representing the light source's emission characteristics (e.g., in form of a list or in form of a table). For example, a representation can specify a plurality of rays (e.g., an origin, angles of propagation and an intensity value for each ray) in text form.

In the examples above, a light source including a plurality of LEDs has been discussed for the sake of illustration. However, the characterization device of the present disclosure can be used to any suitable other light source.

For example, the light source can include only a single LED. In other examples, the light source can include two or more, five or more or ten or more LEDs (which can be arranged in a two-dimensional array or in a linear configuration).

In still other examples, the light source can include one or more other types of light emitting elements than LEDs. For instance, the light source can include one or more semiconductor light emitting elements other than LEDs. In still other examples, the light source can include one or more gas-discharge light emitting elements (e.g., high-pressure or low-pressure discharge light emitting elements). In still other embodiments, the light source can include one or more glow-discharge light emitting elements.

Moreover, the light source can include one or more components arranged between a location of the light source where light can be (initially) generated and a surface or surface area of the light source where light can exit the light source, possibly after wavelength conversion, (also called “secondary light source”) to be characterized with the techniques of the present disclosure.

The one or more components can include passive components. For instance, the one or more components can include components to steer light (e.g., by refraction, reflection or elastic scattering).

In one example, the one or more component can be an elastic scattering element or a lens element. In this example, the techniques of the present disclosure can be used to characterize output light at the surface of the elastic scattering element or lens element.

In another example, the light source can include a homogenizer (e.g., a mining rod) which can provide homogenized light at an output surface.

In still other examples, the one or more components can include a non-elastically scattering component (e.g., a component containing a phosphor). In this example, the surface of the light source can be formed (at least partially) by the non-elastically scattering component.

As can be seen from these examples, the light source to be characterized can be an assembly of light-emitting and light-steering or light-converting elements. In any case, the surface (or a portion of the surface) of the assembly from which the light can exit into the environment can be characterized by the techniques of the present disclosure.

Different examples of the actuator effecting the relative translation of the support and the imaging optics will be discussed next. It has been discussed above that the actuator can be configured to effect the relative movement of the support 1 and the imaging optics 2, 3 to allow for capturing different surface areas of a light source to be characterized.

In one example, the support 1 can be coupled to the translation actuator. In this example, laterally shifting can include keeping the imaging optics 2, 3 stationary while the support 1 (and with it the light source) is laterally shifted. In other examples, the imaging optics 2, 3 can be coupled to the translation actuator. In this example, laterally shifting can include keeping the support 1 (and with it the light source) stationary while laterally shifting the imaging optics 2, 3.

In still other examples, the translation actuator can be configured to laterally translate both the support 1 and the imaging optics 2, 3 to effect a relative translation.

In any case, the translation actuator can include any actuator suitable to effect a one-dimensional or two-dimensional translation of the respective component coupled to the actuator.

For example, the translation actuator can include a linear electric motor. However, in other examples, the translation actuator may be a pneumatic or hydraulic actuator.

In some examples, translation in two orthogonal directions may be necessary to scan a complete surface of the light source. However, in other examples, the translation actuator may only be configured to translate the support 1 and the imaging optics 2, 3 relative to each other in one direction or one dimension.

As discussed above, the translation activator may be controlled by a controller of the characterization device. The controller may be programmable so that the translation actuator scans through a predetermined pattern to image different portions of the surface of the light source automatically. In addition alternatively, the image generation process may also be automatized. In this manner, the characterization system of FIG. 1 may be adapted to automatically perform characterization measurements of a light source.

As can be seen in FIG. 1, the relative translation can happen in a direction which can be substantially orthogonal to the main axis of the optical system. In a conventional microscope set-up, the translation directions may be referred to as x-direction and y-direction (the third direction being the z-direction).

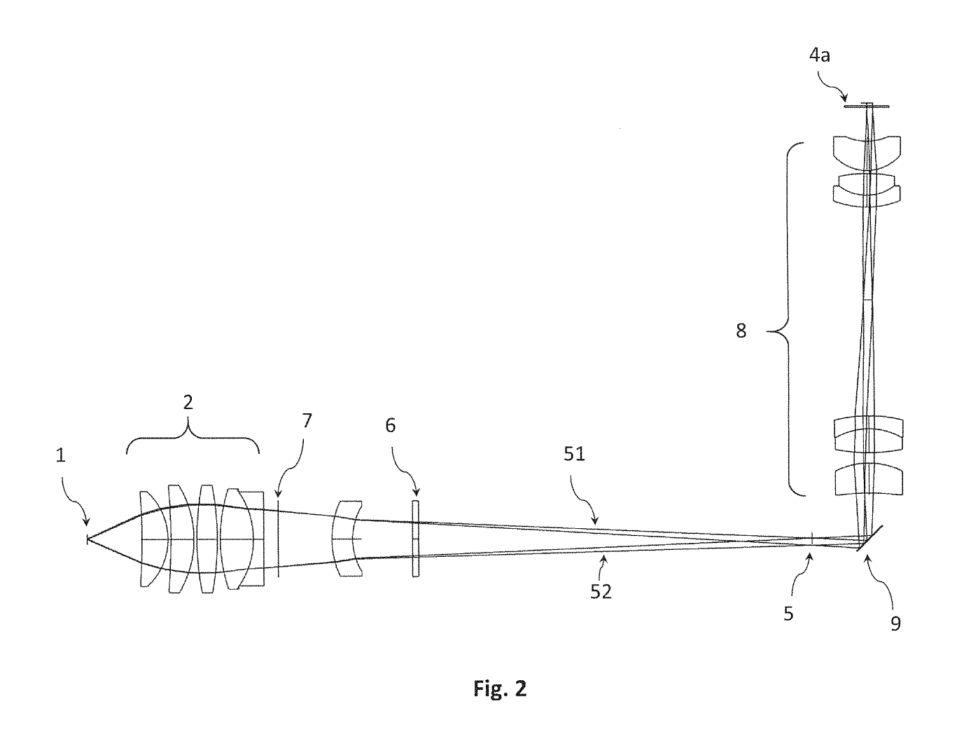

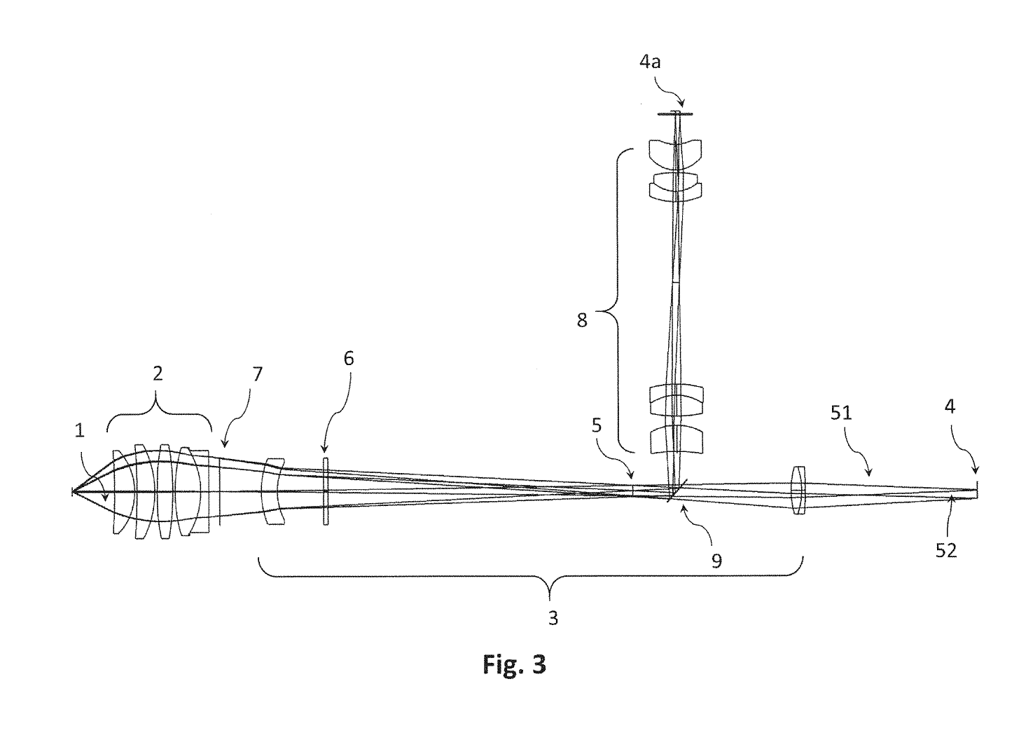

The main components of the system of FIG. 1 have been explained above. In the subsequent sections, several additional components the characterization device may contain, in some examples, will be discussed next in connection with FIG. 2 and FIG. 3.

FIG. 2 shows a portion of an example characterizing system according to the present disclosure. As can be seen, the system can include a folding mirror 9 arranged in the light path of the imaging optics. In some examples, the folding mirror can be a semi-transparent mirror which only reflects a portion of the light traversing the imaging optics. In other examples, the folding mirror 9 can be arranged in a removable manner (e.g., it can be pivoted into and out of the optical path). In these examples, the folding mirror 9 can be inserted in the light path (e.g. for adjustment purposes) and then removed again.

The characterization system of FIG. 2 can additionally include a third optics assembly 8. The third optics assembly 8 can be configured to generate an image of the surface of the light source to be characterized on a second detector 4a. In this manner, the imaging system can provide the capability to directly inspect an image of the light source to the characterized. This can be helpful for adjusting the light source's position before starting capturing the pupil images. For instance, a starting point of the scanning motion over the surface of the light source can be selected at a predetermined position (e.g. in the center of the surface of the light source or at the corner of the surface of the light source). The second detector can include a matrix detector (e.g., a CCD or CMOS detector).

A complete set-up of a characterization system including a first arm including the detector 4 for capturing pupil images of a surface of a light source to be characterized and a second arm including the detector 4a for capturing an image of the surface of a light source to be characterized (e.g. for adjustment purposes) is shown in FIG. 3.

As can be seen, the pupil imaging path can be arranged in a first arm of the imaging device or the field imaging path can be arranged in a second arm of the characterization device. The light propagating in the imaging optics can be split between the two paths by a semitransparent mirror 9 arranged in the light path. In other examples, an arrangement of the two arms can be reversed.

As also shown in FIG. 3, the first and second arms can share several optical components. In other examples, the first and second arms can have separate optical components.

In the preceding sections, techniques to characterize the emission properties of a light source have been discussed. Similar techniques can also be used to characterize the emission properties of a sample in a sample analyzer (e.g. an in-vitro analyzer for analyzing samples). Different aspects of this application of the techniques of the present disclosure will be discussed subsequently in connection with FIG. 5.

FIG. 5 shows an analyzer for analyzing a sample including a sample support 1 for receiving a sample to be analyzed, a matrix detector 4 and imaging optics 2, 3. The imaging optics 2, 3 can be configured to collect light emitted from the sample, generate a pupil 7 of the collected light emitted from the sample and generate an image of the pupil of the sample at a matrix detector 4 so that rays having different angular directions when emanating from the sample can be imaged onto different locations at the matrix detector 4.

As can be seen, the analyzer of FIG. 5 has certain similarities to the characterization system of FIG. 1. In particular, the imaging optics 2, 3 can be set up in a similar manner. The only difference being that instead of the second lens element of the second optics assembly and the field stop shown in FIG. 1, the analyzer of FIG. 5 can include a field lens array 15. This field lens array 15 can be arranged in a field plane of the imaging optics 2, 3. Accordingly, the propagation of the rays of light emanating from the sample surface can be similar to the propagation of the light of the light source in the device of FIG. 1 until the rays reach the field plane of the second optics assembly 3.

As explained above, in the field plane an image of the surface of the sample to be analyzed can be formed. Therefore, light emanating from different surface areas of the sample can impinge on different lens elements of the field lens array 15. As also shown in FIG. 5, each lens element of the field lens array 15 can focus light onto a different spatial area of the matrix detector 4. In other words, the field lens array 15 can be designed so that images of pupils of different surface areas of the sample can be imaged onto separate areas of the detector. These different images may not overlap. As a consequence, this set up of FIG. 5 can capture pupil images of a plurality of separate surface areas of the sample at one time.

Additional explanations regarding the operation principle of the analyzer of FIG. 5 will now be given in connection with FIGS. 6a-b.

FIG. 6a is an enlarged view of the sample surface to be characterized. As can be seen, a group of parallel rays of light 56a, 56b, 56c, 56d can emanate from the sample surface. As these rays of light 56a, 56b, 56c, 56d propagate under the same angle (e.g., compared to the main axis, they can traverse the same spatial position in the pupil 7 (see FIG. 5).

As now can be seen in FIG. 6b, the different rays can hit different lens elements 15a, 15b, 15c of the field lens array. These different lens elements can be arranged and selected so that an image generated on the detector plane does not overlap with images generated by other lens elements 15a, 15b, 15c.

Going back to FIG. 5, the imaging optics 2, 3 can be configured to guide rays propagating from the surface of the sample under different angles than the example rays 53, 54 in the same manner as the example rays 53, 54. In particular, rays propagating from a particular surface area of the sample can be guided towards the same lens element of the field lens array 15 (since the field lens array 15 can be arranged in a field plane of the imaging optics).

In this manner, each lens element of the field lens array 15 can generate a pupil image of a particular surface area of the sample under investigation. Therefore, the analyzer of FIG. 5 can process a plurality of sample positions in parallel.

In the example of FIG. 5, the field lens array 15 is shown including a number of lens elements. It can be pointed out that FIG. 5 only shows a section through the field lens array which can include a two dimensional array of lens elements.

In other examples, a different component including two or more optical elements than a field lens array can be arranged between the sample and the detector so that each of the two or more optical elements can be configured to generate an image of a pupil of light emitted from a different surface area of the sample on the detector and that the images of pupils of light emitted from the different surface areas of the sample on the detector do not overlap.

Moreover, a number of lens elements in the field lens array 15 (or optical elements in a different component) can be different in different examples. The number of lens elements shown in FIG. 5 is for illustrative purposes only. Similar to the device of FIG. 1, a size of each lens element can be selected to determine a spatial resolution of the pupil images of the sample. For instance, if smaller lens elements are deployed, each partial pupil image on the detector can include rays emanating from a smaller surface area of the sample.

The different areas of the sample imaged in parallel by the analyzer of FIG. 5 can belong to the same sample (e.g., an analyte in a cuvette or other sample receptacle) or to different samples.

For example, the different areas may be associated with different sample positions of a multi-vessel sample holder of the analyzer. In one example, the sample support 1 can support a sample holder having a plurality of receptacles for receiving a plurality of samples. For instance, the sample support 1 may be configured to hold a plurality of cuvettes, a multiwell plate, a plurality of test tubes or a plurality of other vessels to hold samples. Then, the analyzer of FIG. 5 can simultaneously image the pupils of light emanating from each (or a subset of) this plurality of samples (e.g., a plurality of wells of a multiwell plate).

One example analyzer according to the present disclosure can include a plurality of cuvettes which can be measured in transmission. In this system, the device of FIG. 5 can be employed to perform a parallel measurement of the scattering properties of samples in each of the plurality of cuvettes.

The analyzer of FIG. 5 can be any of the analyzers discussed in the summary section above. In particular, the analyzer can be an in vitro analyzer for analyzing biological samples. In one example, the analyzer can be configured to perform turbidimetric measurements.

The analyzer can include additional components to the components discussed in connection with FIG. 5. In general, the analyzer can be set up in different ways.

For example, the analyzer can include an illumination source for illuminating the sample. The light captured by the imaging optics 2, 3 shown in FIG. 5 can be linearly or nonlinearly scattered light emanating from the sample in response to illumination by the illumination source (e.g., fluorescent or other luminescent light).

The illumination source can be arranged in different relationships compared to the imaging optics. In one example, the illumination source can be arranged in an epi-illumination setup. In other words, the illumination light can arrive at the same side of the sample at which the imaging optics 2, 3 can be arranged. For example, the illumination source may illuminate the sample under an oblique angle. In other examples, the illumination light generated by the illumination source may be guided towards the sample via (at least some) of the optical components of the imaging optics 2, 3. For example, the first set of optical components 2 may also be arranged to focus illumination light onto the sample.

In other examples, the illumination source can be arranged in a trans-illumination setup. In other words, the illumination light can arrive at the sample on a different side compared to the side where the imaging optics 2, 3 can be arranged. For example, the illumination source may be arranged to shine light through the sample which can then be collected by the imaging optics 2, 3.

As explained above, the system of FIG. 5 can characterize the angle the characteristics of light emitted from the sample. In this manner, scattering characteristics of a sample can be obtained. This may be useful to draw conclusions regarding a composition of the sample. For example, a concentration of substances having particular scattering processes can be used.

In some known analyzers, the angular properties of the light emanating from the sample may not have been resolvable. The light emanating in different direction can be integrated at the detector. The technique of the present disclosure can provide additional information regarding the sample compared to these known analyzers.

In some examples, the analyzers of the present disclosure can include (or a coupled to) a computing device which can derive a spatially resolved image of the sample, or draw conclusions regarding a composition of the sample based on the emission pattern data derive by employing the techniques of the present disclosure. For examples, the computing device may use information regarding the scattering properties of a predetermined substance to infer a concentration of this substance using the information gathered by the techniques of the present disclosure.

In the example of FIG. 5, a field lens array 15 can be used to separate the pupil images of different areas of the sample to be analyzed. However, in other examples, other optical elements may be used to fulfill this task. In addition, in still other examples, the analyzer may be set up in a similar manner as the characterizing system for a light source of FIG. 1.

It can be seen, that instead of generating the pupil images of different portions of the sample in parallel as in the system of FIG. 5, a sequential technique as employed in the system of FIG. 1 can also be used. Therefore, even though in connection with FIG. 1 only the characterization of light source is discussed, the techniques discussed can also be used to sequentially characterize a sample (e.g. in an automated sample analyzer for samples).

The techniques of the present disclosure can involve method steps which can be executed by a computerized system (e.g., the relative movement of the sample and imaging optics or the capturing and processing of pupil images). The present disclosure can also relate to a computer-readable medium having instructions stored thereon which when executed by a system make the system perform the operations according to the present disclosure. Furthermore, the present disclosure can also relate to an electric signal carrying instructions which when executed by a system can make the system perform the operations according to the present disclosure.

The preceding detailed description provides multiple examples methods for characterizing light sources and other samples, and devices for characterizing light sources and other samples. However, the methods for characterizing light sources and other samples, and to devices for characterizing light sources and other samples can also be configured as set out in the following:

A method for characterizing a light source is presented. The method can comprise providing a light source to be characterized and collecting light emitted from the light source by using imaging optics. The imaging optics generating a pupil of the collected light can be emitted from the light source. The method also comprises generating an image of a pupil of light emitted only from a first surface area of the light source at a detector using the imaging optics, laterally shifting the light source and the imaging optics relative to each other, and, after the lateral shift, generating an image of a pupil of light emitted only from a second surface area of the light source at the detector using the imaging optics. The imaging optics can include a field stop between the light source and the detector to select a portion of the light source's surface from which light is imaged at a time.

Laterally shifting can include keeping the light source stationary while the imaging optics is laterally shifted. Laterally shifting can include keeping the imaging optics stationary while the light source is laterally shifted.

The method can further comprise repeatedly laterally shifting the light source and the imaging optics relative to each other and, after each lateral shift, generating an image of a pupil of light emitted only from a further surface area of the light source different from the previously imaged surface areas at the detector using the imaging optics.

The complete light emitting surface of the light source can be sequentially imaged.

Laterally shifting the light source and the imaging optics can include shifts in two orthogonal directions. A main axis of the imaging optics can be oriented substantially perpendicular to the two orthogonal directions.

The images of the light source's surface can be defocused at the detector.

The imaging optics can include a first optics assembly configured to generate the pupil of light emitted from the light source at its back focal plane. The first optics assembly can include sine corrected optics. The imaging optics can further include a second optics assembly configured to relay the pupil of the light emitted from the light source onto the detector. The field stop can be arranged between the first optics assembly and the detector.

The field stop can be arranged adjacent to the surface of the light source to be characterized.

The method can further comprise providing a color filter between the light source to be characterized and the detector to filter a particular part of a spectrum of the light source to be characterized.

The detector can be a matrix detector.

The method can further comprise generating an image of the surface of the light source to be characterized on a further detector.

The method can further comprise aligning the light source to be characterized based on the image of the surface of the light source to be characterized on the further detector.

Generating an image of surface of the light source to be characterized on the further detector can include using second imaging optics. The first arm and the second arm can share one or more optical components.

The detector detecting an image of the pupil can be arranged in a first arm of a characterization device. The second detector detecting the image of the surface of the light source to be characterized can be arranged in a second arm of the characterization device. A mirror can be arranged to reflect light into the first or the second arm. The mirror can be a partially reflecting mirror so that light can simultaneously reach the first and further detectors.

The light source to be characterized can be a light source of an automated analyzer for samples. For example, the light source can be for an in-vitro analyzer.

The method can further comprise generating a representation of the light source's emission characteristics based on multiple images of pupils of light emitted from multiple surface areas specifying spatial and angular emission characteristics of the light source. The representation of the light source's emission characteristics can characterize a near-field emission pattern of the light source. The representation of the light source's emission characteristics can characterize the light source's emission characteristics in a cone defined by an input numerical aperture of the imaging optics.

The method can further comprise selecting a lateral resolution of the representation of the light source's emission characteristics by selecting a size of the field stop.

The method can further comprise changing a lateral resolution of the representation of the light source's emission characteristics by changing a size of the field stop.

Rays having different angular directions when emanating from the slight source can be imaged onto different locations at the detector. The rays emanating from the light source to be characterized under a certain angle can meet substantially at the same point in the pupil.

A method of analyzing a sample in an analyzer for samples is presented. The method can comprise collecting light emitted from the sample by using imaging optics. The imaging optics can be further configured to generate a pupil of the collected light emitted from the sample. The method can also comprise generating an image of the pupil of the sample at a matrix detector using the imaging optics so that rays having different angular directions when emanating from the sample can be imaged onto different locations at the matrix detector.

The sample can be contained in sample holder. The sample holder can be a microwell plate, a test tube, a cuvette or a slide. The sample can be a biological sample.

In one embodiment, the analyzer for samples can be an in-vitro analyzer. In another embodiment, the analyzer for samples can be a turbidimetry analyzer.

The method can further comprise illuminating the sample. The light emitted from the sample can be generated in response to illuminating the sample.

The light can be predominately inelastically, or predominately elastically, scattered light.

The light can be transmitted or reflected light.

The light can be luminescent light emitted in response to illuminating the sample.

The sample can be illuminated in a trans-illumination setup.

The sample can be illuminated in an epi-illumination setup.

Generating an image of the pupil of the sample at a matrix detector using the imaging optics can include generating two or more images of pupils of light emitted from different surface areas of the sample at different positions of the matrix detector. A two-dimensional array of images of pupils of light emitted from different surface areas of the sample can be generated at the matrix detector. The two or more images can be generated in parallel.

The imaging optics can include a first optics assembly configured to generate the pupil of light emitted from the sample at its back focal plane. The first optics assembly can include sine corrected optics. The imaging optics can further include a second optics assembly configured to relay the pupil of the light emitted from the sample onto the detector.

The imaging optics can include two or more optical elements between the sample and the detector. Each of the two or more optical elements can be configured to generate an image of a pupil of light emitted from a different surface area of the sample on the detector. The two or more optical elements can be selected so that the images of pupils of light emitted from the different surface areas of the sample on the detector do not overlap. The two or more optical elements can be located in an intermediate field plane of a light path of the light emitted from the sample between the sample and the detector. The two or more optical elements can be included in a field lens array. The different surface areas of the sample can be associated with two or more different sample receptacles.

The method can further comprise providing a color filter between the sample to and the detector to filter a particular part of a spectrum of the sample.

A computer-readable medium having instructions stored thereon which when executed by a system make the system perform the operations according to any of the above methods.

A device for characterizing a light source is presented. The device can comprise a support for receiving a light source to be characterized, a detector, and imaging optics configured to collect light emitted from the light source, generate a pupil of the collected light emitted from the light source, and generate an image of a pupil of light emitted only from a particular surface area of the light source at the detector. The device can further comprise a translation actuator configured to laterally shift the support and the imaging optics relative to each other and a controller configured to laterally shift the support and the imaging optics relative to each other and to generate an image of a pupil of light emitted only from a particular surface area of the light source at the detector. The imaging optics can include a field stop between the support for receiving a light source and the detector to select a portion of the light source's surface from which light is imaged at a time.

An analyzer for analyzing a sample is presented. The analyzer can comprise a sample support for receiving a sample to be analyzed, a matrix detector, and imaging optics configured to collect light emitted from the sample, generate a pupil of the collected light emitted from the sample and generating an image of the pupil of the sample at a matrix detector so that rays having different angular directions when emanating from the sample are imaged onto different locations at the matrix detector.

It is noted that terms like “preferably,” “commonly,” and “typically” are not utilized herein to limit the scope of the claimed embodiments or to imply that certain features are critical, essential, or even important to the structure or function of the claimed embodiments. Rather, these terms are merely intended to highlight alternative or additional features that may or may not be utilized in a particular embodiment of the present disclosure.

For the purposes of describing and defining the present disclosure, it is noted that the term “substantially” is utilized herein to represent the inherent degree of uncertainty that may be attributed to any quantitative comparison, value, measurement, or other representation. The term “substantially” is also utilized herein to represent the degree by which a quantitative representation may vary from a stated reference without resulting in a change in the basic function of the subject matter at issue.

Having described the present disclosure in detail and by reference to specific embodiments thereof, it will be apparent that modifications and variations are possible without departing from the scope of the disclosure defined in the appended claims. More specifically, although some aspects of the present disclosure are identified herein as preferred or particularly advantageous, it is contemplated that the present disclosure is not necessarily limited to these preferred aspects of the disclosure.

We claim:

1. A method for characterizing a light source, the method comprising:
providing a light source to be characterized;
collecting light emitted from the light source by using imaging optics, the imaging optics generating a pupil of the collected light emitted from the light source;
generating an image of a pupil of light emitted only from a first surface area of the light source at a detector using the imaging optics;
laterally shifting the light source and the imaging optics relative to each other; and
after the lateral shift, generating an image of a pupil of light emitted only from a second surface area of the light source at the detector using the imaging optics, wherein the imaging optics includes a field stop between the light source and the detector to select a portion of the light source's surface from which light is imaged at a time.

2. The method of claim 1, wherein laterally shifting includes keeping the imaging optics stationary while the light source is laterally shifted.

3. The method of claim 1, further comprising,
repeatedly laterally shifting the light source and the imaging optics relative to each other; and
after each lateral shift, generating an image of a pupil of light emitted only from a further surface area of the light source different from the previously imaged surface areas at the detector using the imaging optics.

4. The method of claim 1, wherein the imaging optics includes a first optics assembly configured to generate the pupil of light emitted from the light source at its back focal plane.

5. The method of claim 4, wherein the first optics assembly includes sine corrected optics.

6. The method of claim 4, wherein the imaging optics further include a second optics assembly configured to relay the pupil of the light emitted from the light source onto the detector.

7. The method of claim 1, further comprising,
generating an image of the surface of the light source to be characterized on a further detector.

8. The method of claim 1, further comprising,
generating a representation of the light source's emission characteristics based on multiple images of pupils of light emitted from multiple surface areas specifying spatial and angular emission characteristics of the light source.

9. The method of claim 1, further comprising,
selecting a lateral resolution of the representation of the light source's emission characteristics by selecting a size of the field stop.

10. The method of claim 1, wherein rays having different angular directions when emanating from the slight source are imaged onto different locations at the detector.

11. An analyzer for analyzing a sample, the analyzer comprising:
a sample support for receiving a sample to be analyzed;
a matrix detector; and
imaging optics configured to:
collect light emitted from the sample,
generate a pupil of the collected light emitted from the sample, and
generating an image of the pupil of the sample at a matrix detector so that rays having different angular directions when emanating from the sample are imaged onto different locations at the matrix detector.

12. The analyzer of claim 11, wherein the analyzer for samples is an in-vitro analyzer.

13. The analyzer of claim 12, wherein the analyzer for samples is a turbidimetry analyzer.

14. The analyzer of claim 11, wherein generating an image of the pupil of the sample at a matrix detector using the imaging optics includes generating two or more images of pupils of light emitted from different surface areas of the sample at different positions of the matrix detector.

15. The analyzer of claim 11, wherein the imaging optics includes a first optics assembly configured to generate the pupil of light emitted from the sample at its back focal plane.

16. The analyzer of claim 15, wherein the first optics assembly includes sine corrected optics.

17. The analyzer of claim 15, wherein the imaging optics further include a second optics assembly configured to relay the pupil of the light emitted from the sample onto the detector.

18. The analyzer of claim 11, wherein the imaging optics includes two or more optical elements between the sample and the detector and wherein each of the two or more optical elements is configured to generate an image of a pupil of light emitted from a different surface area of the sample on the detector.

19. The analyzer of claim 18, wherein the two or more optical elements are selected so that the images of pupils of light emitted from the different surface areas of the sample on the detector do not overlap.
